(19) United States
(12) Patent Application Publication
(10) Pub. No.: US 2014/0144688 A1
(43) Pub. Date: May 29, 2014

(54) CIRCUIT BOARD AND METHOD OF MOUNTING ELECTRONIC COMPONENT ON CIRCUIT BOARD

(71) Applicant: SAMSUNG DISPLAY CO., LTD., YONGIN-CITY (KR)

(72) Inventors: CHUNG-WON CHOI, Seoul (KR); Seok Hwan Lee, Seoul (KR); Min-Soo Choi, Asan-Si (KR)

(73) Assignee: SAMSUNG DISPLAY CO., LTD., YONGIN-CITY (KR)

(21) Appl. No.: 13/833,729

(22) Filed: Mar. 15, 2013

(30) Foreign Application Priority Data
Nov. 29, 2012 (KR) 10-2012-0137018

(51) Int. Cl. H05K 1/18; H05K 13/04

(52) U.S. Cl. CPC H05K 1/181; H05K 13/0465
USPC 174/260; 228/180.21

(57) ABSTRACT

Provided are a circuit board, and a method of mounting an electronic component on the circuit board. The circuit board according to an exemplary embodiment of the present invention includes: a pad pattern including a basic pattern and one or more additional patterns connected to the basic pattern, in which the basic pattern includes a region in which a connection terminal of an electronic component is attached by solder, the one or more additional patterns include regions in which the connection terminal of the electronic component is not attached, and the basic pattern includes an exposed side or an exposed point capable of limiting a mounting position so as to prevent the electronic component from exceeding an alignment margin.

### CROSS-REFERENCE TO RELATED APPLICATION

This application claims priority to and the benefit of Korean Patent Application No. 10-2012-0137018 filed in the Korean Intellectual Property Office on Nov. 29, 2012, the entire contents of which are incorporated herein by reference.

### TECHNICAL FIELD

The present invention relates to a circuit board, and more particularly, to a circuit board and a method of mounting an electronic element on the circuit board.

### DISCUSSION OF THE RELATED ART

An electronic device, such as a display device, includes a plurality of electronic components, such as a transistor, a diode, s resistor, and an IC chip. In general, the electronic components may be mounted on various circuit boards, such as a printed circuit board, by methods such as soldering and the like. The printed circuit board is formed by printing a circuit pattern with a conductive material, such as copper, on an insulation substrate. The circuit pattern includes a connection pattern for connecting external electronic components.

An electronic component may be mounted on a circuit board through a surface mounting technology (SMT), which is a form of soldering. The surface mounting technology involves connecting lead frames of the electronic components and the pad of the circuit board by printing solder on the pad of the circuit board, aligning and mounting lead frames of the electronic component on the pad on which the solder is printed, and melting the solder by applying heat to the circuit board.

For example, a display device includes a plurality of pixels and a plurality of display signal lines. Each pixel includes a switching element and a pixel electrode connected to the switching element. The switching element is connected with the display signal lines such as gate lines and data lines. The pixel electrode may receive a data signal, such as a gate signal, through the switching element, such as a thin film transistor. The gate signal may be generated in a gate driving unit, and the data signal may be generated in a data driving unit. The driving units, which are electronic components, include at least one integrated circuit (IC) chip. The IC chips may be directly mounted on a thin film transistor display panel on which the plurality of pixels are formed by a surface mounting technology or the like. Alternatively, the driving units may be mounted on a flexible printed circuit layer or a printed circuit board by a surface mounting technology or the like. The driving units may be attached to and connected with the thin film transistor display panel.

In a display device including a backlight, the backlight may include a printed circuit board on which an electronic component, such as an LED package, is mounted by a surface mounting technology or the like.

The electronic component mounted on the circuit board as described above is electrically connected with a pad through a solder, and the solder includes a solder fillet which is formed along a side surface of the electronic component and higher than a bottom surface of the electronic component. When the solder fillet is not properly formed, poor contact results between the mounted electronic component and the circuit board, so that the electronic component may be separated.

When the electronic component is fixed on the pad of the circuit board, the electronic component may be fixed on a plane of the circuit board while being inclined based on a predetermined direction or fixed while being pulled in a certain direction. For example, in a case where the electronic component is an LED package, when the LED package is fixed at an incline, the LED package is misaligned with respect to another component, such as a light guide plate, so that luminance becomes non-uniform, thereby causing deterioration of a display quality.

### SUMMARY

Exemplary embodiments of the present invention prevent a poor connection, such as may be caused by separation of an electronic component, and assure structural reliability under tensile force by sufficiently forming a solder fillet when the electronic component is soldered on a circuit board by a surface mounting technology.

Further, exemplary embodiments of the present invention prevent defects due to misalignment by fixing an electronic component on a circuit board in a normal direction without inclination.

An exemplary embodiment of the present invention provides a circuit board, including: a pad pattern including a basic pattern and one or more additional patterns connected to the basic pattern. The basic pattern includes a region in which a connection terminal of an electronic component is attached by solder. The one or more additional patterns include regions in which the connection terminal of the electronic component is not attached. The basic pattern includes an exposed side or an exposed point capable of limiting a mounting position so as to prevent the electronic component from exceeding an alignment margin.

An exemplary embodiment of the present invention provides a method of mounting an electronic component on a circuit board including a pad pattern including a basic pattern and one or more additional patterns connected to the basic pattern. The method includes printing a solder paste on the pad pattern. The electronic component and the pad pattern are electrically connected by aligning the electronic component over the pad pattern on which the solder paste is applied and reflowing the solder paste. The basic pattern includes a region in which a connection terminal of an electronic component is attached by solder. The one or more additional patterns include a region in which the connection terminal of the electronic component is not attached. The basic pattern includes an exposed side or an exposed point capable of limiting a mounting position so as to prevent the electronic component from exceeding an alignment margin.

The basic pattern may include four sides extending in four directions, respectively.

A side of the basic pattern to which the one or more additional patterns are connected among the four sides of the basic pattern is referred to as a first side. A length of a boundary line between the one or more additional patterns connected to the first side and the first side may be smaller than a length of the first side. A portion of the first side which is not connected with the one or more additional patterns and is exposed may form the exposed side.

A length of the exposed side may be greater than or equal to approximately 1/10 of the length of the first side.

The one or more additional patterns may be simultaneously in contact with two adjacent sides among the four sides of the basic pattern.

The solder may include a solder fillet formed along a side surface of the electronic component, and the solder fillet may include solder positioned on the one or more additional patterns.

The basic pattern may include four sides extending in four directions, respectively. A side of the basic pattern to which the one or more additional patterns are connected among the four sides of the basic pattern is referred to as a first side. A length of a boundary line between the one or more additional patterns connected to the first side and the first side may be approximately the same as a length of the first side. An angle between a tangential line contacting the additional pattern at a contact point of a side of the additional pattern and a side of the basic pattern and a first direction in which the first side faces may be smaller than an angle between a tangential line contacting the basic pattern at the contact point and the first direction. The contact point may form the exposed point.

A shape of the one or more additional patterns may be a circle, an ellipse, or a polygon having an acute angle at the exposed point.

According to an exemplary embodiment of the present invention, it is possible to prevent poor connection, such as separation of an electronic component and increase reliability against tensional force by forming a sufficient solder fillet when the electronic component is solder on a circuit board by the surface mounting technology.

Further, an electronic component may be fixed in a normal direction without being inclined on a circuit board, thereby preventing defects due to misalignment.

A printed circuit board includes an insulating substrate. A circuit pattern is formed on the insulating substrate. A solder resist layer is formed on the circuit pattern. An opening in the solder resist layer exposes a connection pattern of the circuit pattern. A pad pattern is formed on the solder resist layer. The pad pattern electrically and physically connects to the connection pattern and supplements adhesion between the circuit pattern and an external device. The pad pattern includes a basic pattern and one or more additional patterns connected to the basic pattern. The external device is attached by solder to a first region of the basic pattern and is not attached to the one or more additional patterns. The basic pattern includes an exposed side or an exposed point arranged to limit a mounting position of the external device and to prevent the external device from shifting in excess of a predetermined alignment margin.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view of a circuit board and an electronic component connected to the circuit board according to an exemplary embodiment of the present invention;

FIG. 2 is a perspective view of a circuit board and an electronic component connected to the circuit board according to an exemplary embodiment of the present invention;

FIGS. 3A to 5D are top plan views illustrating various pad patterns of the circuit board according to an exemplary embodiment of the present invention;

FIG. 6 is a perspective view of the pad pattern of the circuit board according to an exemplary embodiment of the present invention;

FIG. 7 is a perspective view of the circuit board in which a solder paste is printed on the pad pattern illustrated in FIG. 6;

FIG. 8 is a perspective view illustrating a state in which a lead frame of the electronic component is connected and fixed on the circuit board illustrated in FIG. 7;

FIG. 9 is a cross-sectional view of the circuit board according to an exemplary embodiment of the present invention on which the electronic component is soldered;

FIG. 10 is a perspective view of the pad pattern of the circuit board and the lead frame of the electronic component according to an exemplary embodiment of the present invention; and

FIG. 11 is a perspective view illustrating a state in which the electronic component is connected and fixed on the circuit board illustrated in FIG. 10.

### DETAILED DESCRIPTION OF THE EMBODIMENTS

Exemplary embodiments of the present invention will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., may be exaggerated for clarity. Like reference numerals may designate like elements throughout the specification. It will be understood that when an element such as a layer, film, region, or substrate is referred to as being “on” another element, it can be directly on the other element or intervening elements may also be present.

A circuit board according to an exemplary embodiment of the present invention will be described in detail below with reference to the drawings.

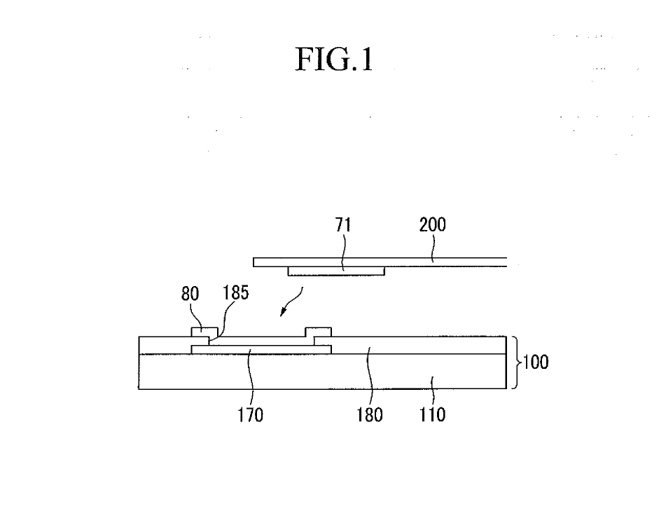

A circuit board according to an exemplary embodiment of the present invention will be described with reference to FIG. 1.

FIG. 1 is a cross-sectional view of a circuit board and an electronic component connected to the circuit board according to an exemplary embodiment of the present invention.

Referring to FIG. 1, a circuit board 100 according to an exemplary embodiment of the present invention may be a printed circuit board. The circuit board includes an insulation substrate 110 on which various circuit patterns 170 are formed.

The circuit patterns 170 may include various signal lines for transmitting driving signals for driving an electronic device, such as a display device, in which the circuit board 100 is included. The circuit pattern 170 may include a connection pattern for connecting with an external device. The circuit pattern 170 may include a conductive material, such as aluminum (Al) or an aluminum-based metal such an aluminum alloy, silver (Ag) or a silver-based metal such as a silver alloy, a copper or a copper-based metal such as a copper alloy, molybdenum (Mo) or a molybdenum-based metal such as a molybdenum alloy, and/or a metal, such as chromium (Cr), tantalum (Ta), and/or titanium (Ti).

A solder resist layer (also referred to as a passivation layer) 180 formed of an insulating material is positioned on the circuit pattern 170. The solder resist layer 180 protects the circuit board 100, and includes an opening 185 through which the connection pattern of the circuit pattern 170 is exposed.

A pad pattern 80 may be positioned on the solder resist layer 180. The pad pattern 80 may be electrically and physically connected with the connection pattern of the circuit pattern 170 through the opening 185 of the solder resist layer 180. The pad pattern 80 may be formed of a transparent conductive material, such as IOT and/or IZO, or a conductive material, such as a metal. The pad pattern 80 may supplement adhesion between the circuit pattern 170 and an external device and protect the circuit pattern 170 and the external device.

The pad pattern 80 positioned on the solder resist layer 180 may be omitted, and the connection pattern of the circuit pattern 170 exposed through the opening 185 of the solder resist layer 180 may be directly formed as the pad pattern 80. In this case, an edge of the pad pattern 80 is defined by the solder resist layer 180.

Various electronic components, such as a transistor, a diode, a resistor, and an IC chip, may be mounted on the circuit board 100 according to an exemplary embodiment of the present invention.

For example, the electronic component may be a circuit board 200, such as a flexible printed circuit layer, as illustrated in FIG. 1. Various circuit patterns may be formed on the circuit board 200, similar to the circuit board 100, and a driving circuit in a form of an integrated circuit chip may be mounted on the circuit board 200. The circuit board 200 includes a connection terminal for connecting to an external device such as the circuit board 100. FIG. 1 illustrates a pad part 71 positioned on the circuit board 200 as an example of the connection terminal.

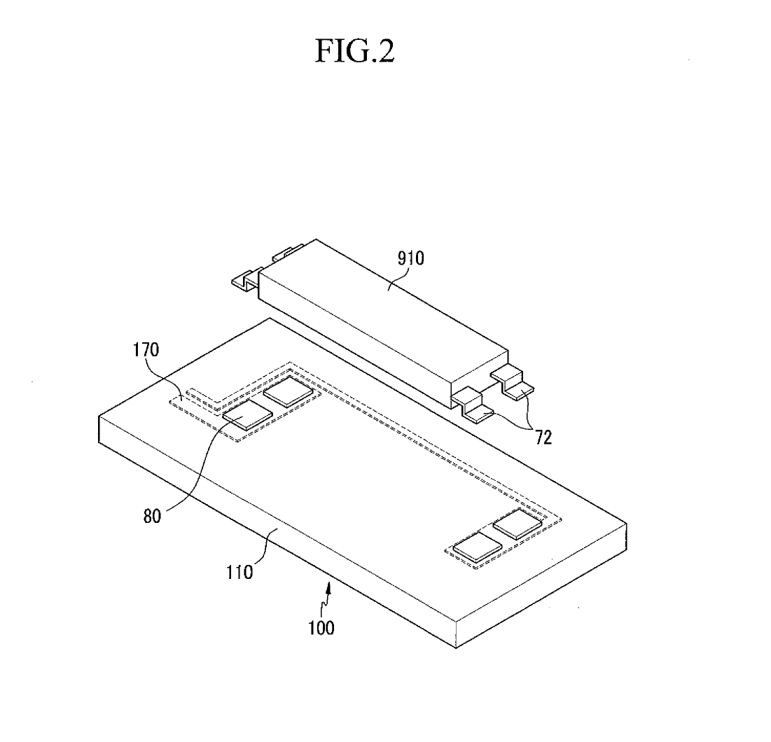

An example of a circuit board and an electronic component connected to the circuit board according to an exemplary embodiment of the present invention will be described with reference to FIG. 2.

FIG. 2 is a perspective view of a circuit board and an electronic component connected to the circuit board according to an exemplary embodiment of the present invention.

The exemplary embodiment illustrated in FIG. 2 is substantially similar to the exemplary embodiment illustrated in FIG. 1, but FIG. 2 illustrates an example in which the electronic component mounted on the circuit board 100 is an electronic component package 910, such as an LED package. The electronic component package 910 may include lead frames 72 as connection terminals for connecting with an external device, such as the circuit board 100.

The connection terminals of the various electronic components may be connected with the pad pattern 80 of the circuit board 100 through soldering. A surface mounting technology (SMT) may be used as one method of soldering. For example, the surface mounting technology (SMT) may connect the connection terminals of the electronic component and the pad pattern 80 of the circuit board 100 by printing a solder paste (also referred to as solder cream) on the pad pattern 80 of the circuit board 100 by a screen printing method or the like, aligning and mounting the connection terminals of the electronic component on the pad, and reflowing the solder by applying heat to the circuit board 100.

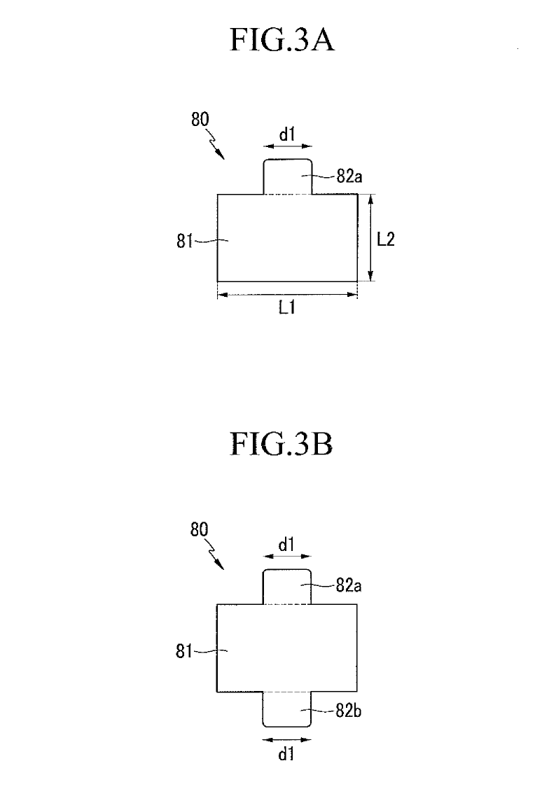

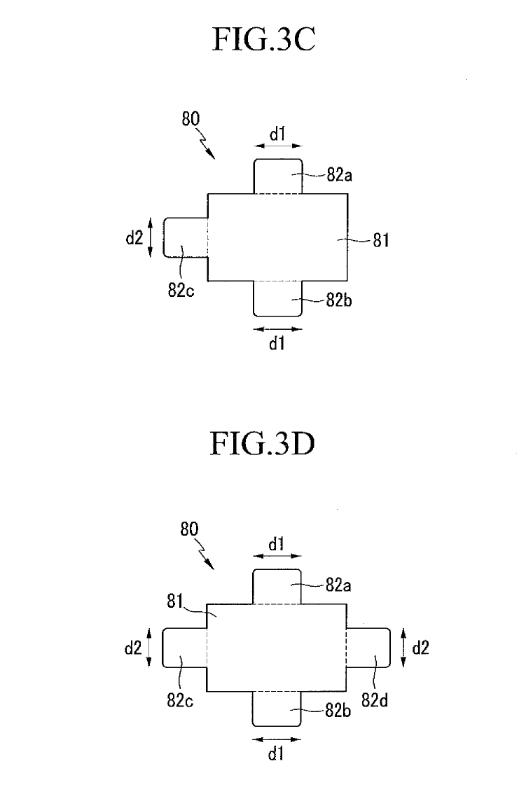

The pad pattern of the circuit board according to an exemplary embodiment of the present invention will be described in detail with reference to FIGS. 3A to 5D together with the aforementioned drawings.

FIGS. 3A to 5D are top plan views illustrating various pad patterns of the circuit board according to an exemplary embodiment of the present invention.

Referring to FIGS. 3A to 5D, the pad pattern 80 of the circuit board according to an exemplary embodiment of the present invention includes a basic pattern 81, and one or more additional patterns 82a, 82b, 82c, 82d, 82e, 82f, 82g, and 82h connected with the basic pattern 81.

The basic pattern 81 includes a region in which a connection terminal of the electronic component is directly connected through the solder in the pad pattern 80. For example, the pad pattern 80 or the region of the connection terminal of the electronic component that is in contact with the solder is included in the region of the basic pattern 81.

The basic pattern 81 may have various shapes, such as a polygon, a circle, and an elliptical shape, as well as shapes of various pads in the related art. FIGS. 3A to 5D illustrate the rectangular basic pattern 81 as an example of the shape of the basic pattern 81.

An edge side of the basic pattern 81 may be divided into four sides extending in four directions, respectively, regardless of the shape of the basic pattern 81. Here, the four directions may be referred to as east, west, south, and north, or as top, bottom, left, and right. For example, when the basic pattern 81 has a rectangular shape, a pair of horizontal sides and a pair of vertical sides may comprise four sides extended in the four directions, respectively. When the basic pattern 81 is shaped like a circle or an ellipse, four curved sides, divided based on four contact points having a gradient of a tangent of 45 degrees or 135 degrees, may comprise four sides extended in the four directions, respectively. However, the sides of the four portions extended in the four directions, respectively, may be asymmetrical with respect to each other and may have different lengths according to the shape of the basic pattern 81.

The additional patterns 82a to 82h each include regions in which the connection terminal of the electronic component is not directly attached in the pad pattern 80. For example, the region of the connection terminal of the electronic component that is not in contact with the pad pattern 80 or the solder does not overlap the regions of the additional patterns 82a to 82h.

The additional patterns 82a to 82h may have various shapes, such as a polygon, a circle, or an ellipse. However, the shapes thereof are not limited to any particular shapes.

The electronic component mounted on the circuit board 100 is mounted in a predetermined region of the circuit board 100, and may have up to a predetermined level of an allowable alignment margin. Here, the alignment margin of the electronic component may be defined as a range within which the electronic component does not have a poor connection with the circuit board 100 or does not lose reliability against influence of external tensional force, and the like. The alignment margin may be variously defined as an allowable shift distance when the electronic component is pulled and mounted in a certain direction based on a predetermined mounting region of the electronic component, an allowable tilt angle when the electronic component rotates or turns on a plane of the circuit board 100, or the like.

The basic pattern 81 according to an exemplary embodiment of the present invention includes an exposed side or an exposed point capable of limiting a mounting position of the electronic component so as to prevent the mounted electronic component from exceeding the alignment margin. Here, the exposed side or the exposed point is based on a shape of the basic pattern 81 on a plane. The basic pattern 81 has a thickness that is not 0 in a direction vertical to a surface of the insulation substrate 110. The exposed side and the exposed point illustrated in the drawing are an exposed surface having an actual (non-zero) area and an exposed side having an actual (non-zero) length, respectively. Hereinafter, exemplary embodiments of the present invention will be described based on the plane shape of the pad pattern 80 for convenience of description.

The exposed sides of the basic pattern 81 is a part of the sides connected with the additional patterns 82a to 82d among the four sides that extend in the four directions, respectively, and may be defined as sides which are exposed without a contact with the additional patterns 82a to 82d. The exposed side may be a part of a straight side of a polygon or a part of a curved side of a circle or an ellipse according to a shape of the basic pattern 81.

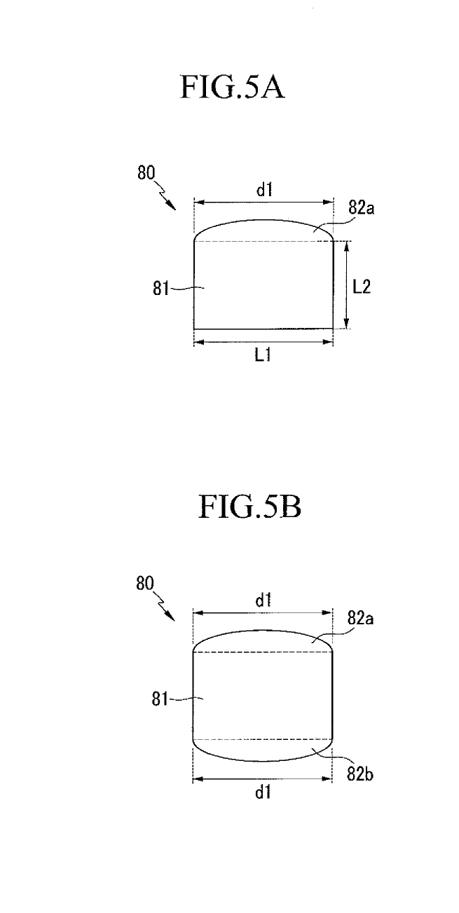

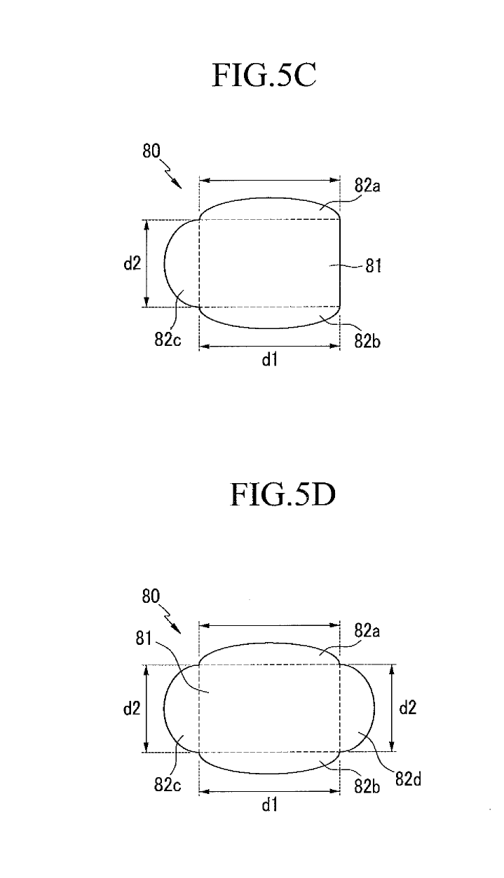

For example, referring to FIGS. 3A to 3D or FIGS. 5A to 5D, one or more additional patterns 82a to 82d are connected to a side extending in a certain direction based on the four directions among the sides of the basic pattern 81.

A length of a boundary line (illustrated by a dotted line) of the additional patterns 82a to 82d and the basic pattern 81 is smaller than an entire length of the side of the basic pattern 81 to which the additional patterns 82a to 82d are connected. For example, the length of the boundary line (illustrated by the dotted line) of the additional patterns 82a to 82d and the basic pattern 81 may be larger than 0, and may be equal to or smaller than approximately 9/10 of the length of the side of the basic pattern 81. For example, the length of the exposed side in one side of the basic pattern 81 may be greater than or equal to approximately 1/10 of the length of the side of the basic pattern 81 to which the additional patterns 82a to 82d are connected.

For example, when the basic pattern 81 is shaped like a rectangle, horizontal length d1 of the additional patterns 82a and 82b connected to the horizontal sides may be smaller than a horizontal length L1 of the basic pattern 81, and particularly, may be equal to or smaller than approximately 9/10 of the horizontal length L1 of the basic pattern 81. Similarly, when the basic pattern 81 is shaped like a rectangle, vertical length d2 of the additional patterns 82c and 82d connected to the vertical sides may be smaller than a vertical length L2 of the basic pattern 81, and particularly, may be equal to or smaller than approximately 9/10 of the vertical length L2 of the basic pattern 81.

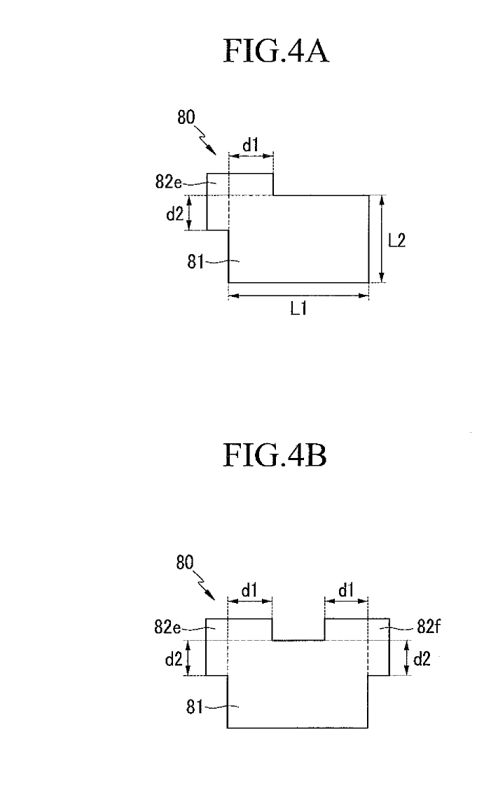

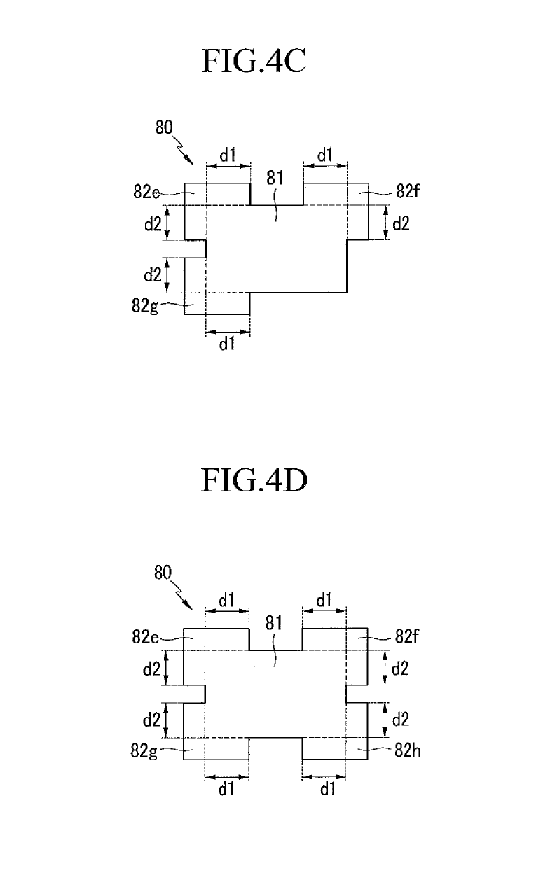

The patterns in FIGS. 4A to 4D may be substantially similar to the exemplary embodiment illustrated in FIGS. 3A to 3D, but FIGS. 4A to 4D illustrate an example in which additional patterns 82e to 82h are simultaneously in contact with the two adjacent sides of the basic pattern 81. For example, the additional patterns 82e, 82f, 82g, and 82h may be simultaneously connected to the two sides connected with at least one vertex of the basic pattern 81. Even in this case, a sum of a length of a boundary line between one or more additional patterns 82e to 82h connected to one side of the basic pattern 81 and the basic pattern 81 is smaller than a length of the side of the basic pattern 81 to which the additional patterns 82e to 82h are connected. For example, the sum of the length of the boundary line between one or more additional patterns 82e to 82h connected to one side of the basic pattern 81 and the basic pattern 81 may be larger than 0 and may be smaller than or equal to approximately 9/10 of the length of the side of the basic pattern 81. For example, a length of an exposed side of one side of the basic pattern 81 may be equal to or larger than approximately 1/10 of the length of the side of the basic pattern 81 to which the additional patterns 82a to 82d are connected.

For example, when the basic pattern 81 is shaped like a rectangle, a sum of a horizontal length d1 of at least one of the additional patterns 82e to 82h that is in contact with the horizontal side of the basic pattern 81 may be smaller than horizontal length L1 of the basic pattern 81. For example, the sum may be equal to or smaller than approximately 9/10 of the horizontal length L1 of the basic pattern 81. Similarly, a sum of a vertical length d2 of at least one of the additional patterns 82e to 82h that is in contact with the vertical side of the basic pattern 81 may be smaller than vertical length L2 of the basic pattern 81. For example, the sum may be equal to or smaller than approximately 9/10 of the vertical length L2 of the basic pattern 81.

The exposed point of the basic pattern 81 is one point of the basic pattern 81 at which the additional patterns 82a to 82d are not formed in a predetermined azimuth range that is not 0 when the additional patterns 82a to 82d are connected to an entire one side of the basic pattern 81 extending in a first direction that is a particular direction among the four directions. The exposed point may be defined as a contact point at which an angle between a tangential line contacting the additional patterns 82a to 82d at a contact point of the side of the additional patterns 82a to 82d and the basic pattern 81 and the first direction is smaller than an angle between a tangential line contacting the basic pattern 81 at the contact point and the first direction. The exposed point may be a vertex of a polygon or one point on a curved line of a circle or an ellipse according to a shape of the basic pattern 81.

For example, referring to FIGS. 5A to 5D, at least one of the additional patterns 82a to 82d is connected to a side extending in a particular direction based on the four directions among the sides of the basic pattern 81. The connected additional patterns 82a to 82d may be connected to an entire one side of the basic pattern 81. For example, the additional pattern 82a connected with the basic pattern 81 extended in a direction of an upper side may be in contact with an entire upper side of the basic pattern 81. In this case, the contact point of the side of the additional pattern 82a and the side of the basic pattern 81 is one of the vertexes of the basic pattern 81, and the contact point may be the exposed point according to the exemplary embodiment of the present invention.

Particularly, the tangential line contacting from the vertex of the basic pattern 81 to the additional patterns 82a to 82d illustrated in FIGS. 5A to 5D approximately faces an right-upper direction, and the tangential line contacting from the vertex to the basic pattern 81 approximately stretches in a horizontal direction. Accordingly, an angle between the tangential line contacting the additional patterns 82a to 82d and an upper direction is smaller than an angle between the tangential line contacting the basic pattern 81 and the upper direction. The vertex of the basic pattern 81 forms the exposed point according to an exemplary embodiment of the present invention. In the aforementioned exemplary embodiment, the additional patterns 82a to 82d connected to the rectangular basic pattern 81 may be shaped like a circle, an ellipse, or a polygon having an acute angle at the vertex. The vertex may be, for example, the exposed point of the basic pattern 81.

When one pad pattern 80 includes the plurality of additional patterns 82a to 82d, the additional patterns 82a to 82d might not be connected to each other. Here, a case in which the additional patterns 82a to 82d are not connected to each other refers to a case in which the adjacent additional patterns 82a to 82d are not connected to each other with a contact surface having a length that is not 0 interposed therebetween.

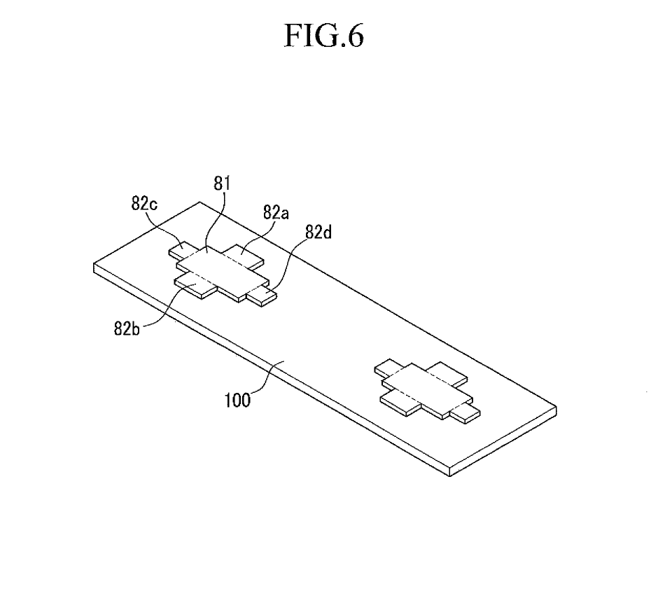

A method of mounting the electronic component on the circuit board according to an exemplary embodiment of the present invention and an effect of the circuit board according to the exemplary embodiment of the present invention will be described with reference to FIGS. 6 to 9 together with the aforementioned drawings.

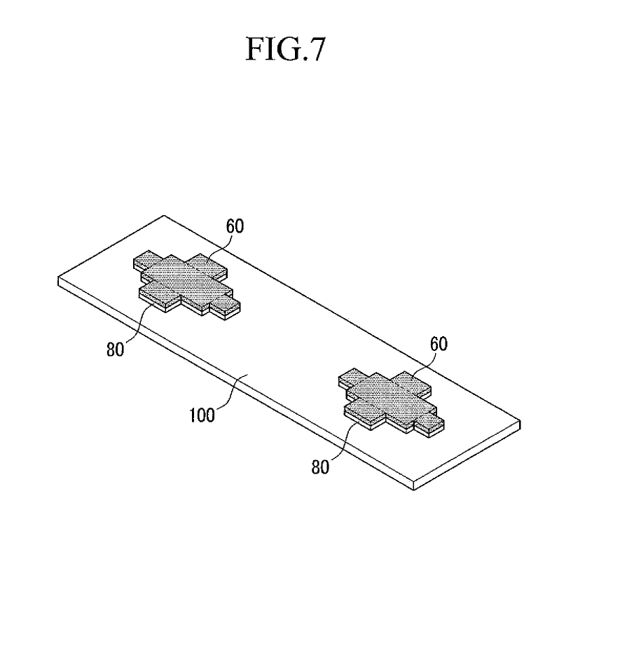

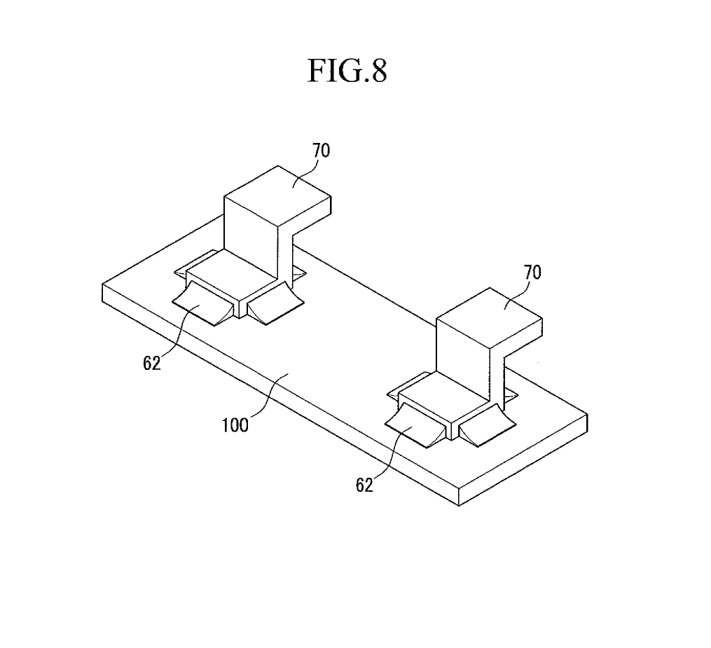

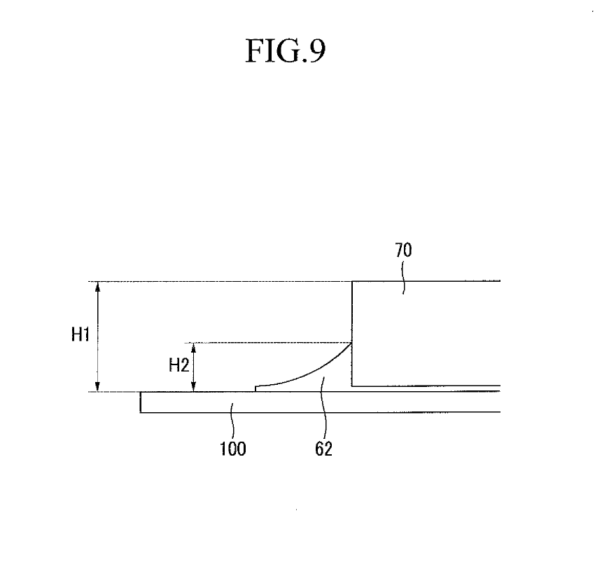

FIG. 6 is a perspective view of the pad pattern of the circuit board according to an exemplary embodiment of the present invention. FIG. 7 is a perspective view of the circuit board in which a solder paste is printed on the pad pattern illustrated in FIG. 6. FIG. 8 is a perspective view illustrating a state in which a lead frame of the electronic component is connected and fixed on the circuit board illustrated in FIG. 7. FIG. 9 is a cross-sectional view of the circuit board according to an exemplary embodiment of the present invention on which the electronic component is soldered.

Referring to FIG. 6, the circuit board 100 according to an exemplary embodiment of the present invention is prepared. The circuit board 100 includes the basic pattern 81, and the pad pattern including one or more additional patterns 82a to 82d. FIG. 6 illustrates the circuit board 100 including the aforementioned pad pattern 80 according to the exemplary embodiment illustrated in FIG. 3D, but the circuit board 100 is not limited to the structure illustrated and the circuit board may include the aforementioned various pad patterns 80. The solder resist layer (not illustrated) including the opening through which the pad pattern 80 is exposed is positioned around the pad pattern 80.

Referring to FIG. 7, the solder paste 60 is printed on the pad pattern 80 of the circuit board 100 by a screen printing method, or the like. The solder paste 60 includes conductive metal powder such as tin (Sn) and a flux. The solder paste 60 may optionally include lead (Pb) as a conductive material. The solder paste 60 may include silver (Ag), copper (Cu), or the like for achieving easy reflow.

Referring to FIG. 8, the connection terminals 70 of the electronic component and the pad pattern 80 of the circuit board 100 are electrically connected to each other by aligning and mounting the connection terminals 70 of the electronic component on the pad pattern 80 on which the solder paste 60 is applied, and reflowing the solder paste 60 by applying heat to the circuit board 100. In FIG. 8, the illustration of the pad pattern 80 is omitted.

Then, as illustrated in FIGS. 8 and 9, the melted solder paste 60 moves up along side surfaces of the connection terminals 70 of the electronic component, and accordingly the solder fillets 62 are formed. The solder fillets 62 may be formed along a side, for example, an exposed side, of the edge of the basic pattern 81. Most of the solder fillets 62 may be formed by the solder positioned on the additional patterns 82a to 82h. For example, most of the solder fillets 62 may be formed along boundary surfaces of the additional patterns 82a to 82h and the connection terminals 70 of the electronic component.

The aforementioned solder fillet 62 prevents poor connection, such as separation of the mounted electronic component from the circuit board 100, and may increase contact reliability against external tensional force by increasing an amount of solder contacting the connection terminals 70 of the electronic component. Accordingly, to increase reliability of the mounted electronic component, a height of the solder fillet 62 needs to be sufficiently high. For example, referring to FIG. 9, an appropriate height H2 of the solder fillet 62 may be set to be greater than or equal to approximately ½ of a height H1 of the connection terminal 70 of the electronic component.

The additional patterns 82a to 82h of the pad pattern 80 are not the regions in which the connection terminals 70 of the mounted electronic components are directly attached, but are connected to the basic pattern 81 to increase the amount of the solder paste 60 applied on the pad pattern 80. Accordingly, it is possible to increase the amount of solder contacting the connection terminals 70 of the electronic component. Accordingly, the height of the solder fillet 62 may become sufficiently high by the sufficient amount of solder on the pad pattern 80. Accordingly, it is possible to prevent poor connection, such as separation of the mounted electronic component, and increase contact reliability by increasing resistance against tensional force.

Further, the basic pattern 81 of the pad pattern 80 is a region in which the connection terminals 70 of the mounted electronic component are directly attached. The basic pattern 81 may prevent the electronic component from being pulled or turned in a certain direction beyond the allowable range including the exposed side or the exposed point as described above. For example, when the side of the basic pattern 81 to which the additional patterns 82a to 82h are connected includes the exposed side or the point at which the two sides of the basic pattern 81 in two directions among the four directions meet forms the aforementioned exposed point, the connection terminals 70 of the mounted electronic component might not get out of the side of the basic pattern 81 to which the additional patterns 82a to 82h are connected when the connection terminals 70 of the mounted electronic component are soldered. Accordingly, the connection terminals 70 of the electronic component are not pulled by a distance greater than or equal to an allowable range or turned at an angle equal to or larger than an allowable range. Accordingly, the connection terminals 70 of the electronic component may be mounted on the circuit board 100 within the alignment margin, thereby preventing defects due to misalignment of the electronic component. Particularly, the length of the exposed side of the basic pattern 81 is formed to be larger than approximately 1/10 of the length of the side of the basic pattern 81 to which the additional patterns 82a to 82h are connected as described above, so that it is possible to more perfectly prevent defects due to misalignment of the electronic component.

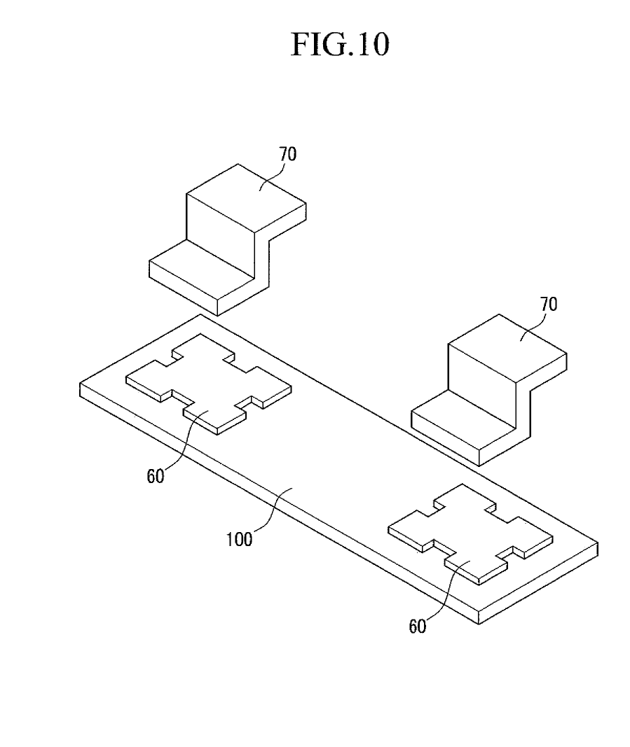

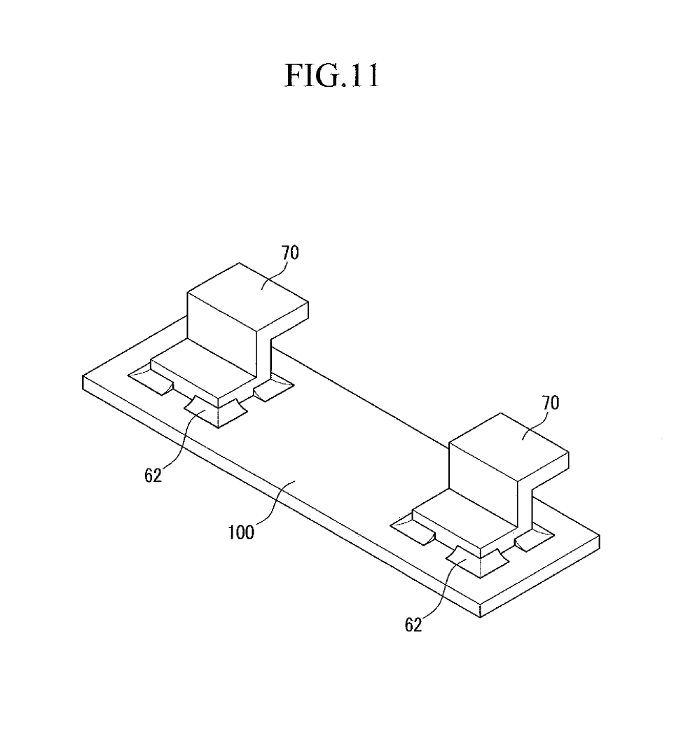

A method of mounting the electronic component on the circuit board according to an exemplary embodiment of the present invention will be described with reference to FIGS. 10 and 11.

FIG. 10 is a perspective view of the pad pattern of the circuit board and the lead frame of the electronic component according to an exemplary embodiment of the present invention. FIG. 11 is a perspective view illustrating a state in which the electronic component is connected and fixed on the circuit board illustrated in FIG. 10.

FIGS. 10 and 11 illustrate a substantially similar method of mounting the electronic component on the circuit board as the aforementioned approach illustrated in FIGS. 6 to 9, but FIGS. 20 and 22 illustrate an example in which a shape of the pad pattern 80 is different. For example, FIGS. 10 and 11 illustrate the circuit board 100 including the pad pattern 80 according to the aforementioned approach illustrated in FIG. 4D.

Referring to FIG. 10, the solder paste 60 is printed on a pad pattern (not illustrated) of the circuit board 100, and the connection terminals 70 of the electronic components are aligned and mounted on the pad pattern.

Referring to FIG. 11, the connection terminals 70 of the electronic component and the pad pattern of the circuit board 100 are electrically connected with each other by reflowing the solder paste 60 by applying heat to the circuit board 100. Then, the solder positioned on the additional pattern among the pad patterns moves up along side surfaces of the connection terminals 70 of the electronic component to form the solder fillets 62 having a sufficient height, and a movement range of the connection terminals 70 of the electronic component is limited by the exposed side of the basic pattern. It is accordingly possible to mount the electronic component within the allowable alignment margin of the connection terminal 70.

While exemplary embodiment of the present invention have been described in detail with reference to the figures, it is to be understood that the invention is not limited to the disclosed embodiments, but, on the contrary, is intended to cover various modifications and equivalent arrangements.

What is claimed is:

1. A circuit board, comprising:
a basic pad pattern; and
one or more additional pad patterns connected to the basic pad pattern,
wherein the basic pad pattern includes a region to which a connection terminal of an electronic component is attached by solder;
wherein the one or more additional pad patterns each include a region in which the connection terminal of the electronic component is not attached, and
wherein the basic pattern includes an exposed side or an exposed point arranged to limit a mounting position of the electronic component so as to prevent the electronic component from exceeding an alignment margin.

2. The circuit board of claim 1, wherein:
the basic pad pattern includes four sides extended in four directions, respectively,
a side of the basic pad pattern to which the one or more additional pad patterns are connected among the four sides of the basic pad pattern is referred to as a first side,
a length of a boundary line between the one or more additional pad patterns connected to the first side and the first side is smaller than a length of the first side, and
the exposed side includes a portion of the first side which is not connected to the one or more additional pad patterns and is exposed.

3. The circuit board of claim 2, wherein:
a length of the exposed side is greater than or equal to approximately 1/10 of the length of the first side.

4. The circuit board of claim 3, wherein:
the one or more additional pad patterns are each in contact with two adjacent sides among the four sides of the basic pad pattern.

5. The circuit board of claim 4, wherein:
the solder includes a solder fillet formed along a side surface of the electronic component, and
the solder fillet is at least partially positioned on the one or more additional pad patterns.

6. The circuit board of claim 3, wherein:
the solder includes a solder fillet formed along a side surface of the electronic component, and
the solder fillet is at least partially positioned on the one or more additional pad patterns.

7. The circuit board of claim 2, wherein:
the one or more additional pad patterns are each in contact with two adjacent sides among the four sides of the basic pad pattern.

8. The circuit board of claim 7, wherein:
the solder includes a solder fillet formed along a side surface of the electronic component, and
the solder fillet is at least partially positioned on the one or more additional pad patterns.

9. The circuit board of claim 2, wherein:
the solder includes a solder fillet formed along a side surface of the electronic component, and
the solder fillet is at least partially positioned on the one or more additional pad patterns.

10. The circuit board of claim 1, wherein:
the solder includes a solder fillet formed along a side surface of the electronic component, and
the solder fillet is at least partially positioned on the one or more additional pad patterns.

11. The circuit board of claim 1, wherein:
the basic pad pattern includes four sides extended in four directions, respectively,
a side of the basic pad pattern to which the one or more additional pad patterns are connected among the four sides of the basic pad pattern is referred to as a first side,
a length of a boundary line between the one or more additional pad patterns connected to the first side and the first side is approximately the same as a length of the first side,
an angle between a tangential line contacting the additional pad pattern at a contact point of a side of the additional pad pattern and a side of the basic pad pattern and a first direction in which the first side faces is smaller than an angle between a tangential line contacting the basic pad pattern at the contact point and the first direction, and
the contact point forms the exposed point.

12. The circuit board of claim 11, wherein:
a shape of the one or more additional pad patterns is a circle, an ellipse, or a polygon having an acute angle at the exposed point.

13. A method of mounting an electronic component on a circuit board comprising a pad pattern including a basic pattern and one or more additional patterns connected to the basic pattern, the method comprising:
printing a solder paste on the pad pattern;
aligning the electronic component over the pad pattern on which the solder paste is applied; and
reflowing the solder paste to electrically connect the electronic component and the pad pattern,
wherein the basic pattern includes a region to which a connection terminal of an electronic component is attached by solder,
the one or more additional patterns include a region in which the connection terminal of the electronic component is not attached, and
the basic pattern includes an exposed side or an exposed point limiting a mounting position of the electronic component so as to prevent the electronic component from exceeding an alignment margin.

14. The method of claim 13, wherein:
the basic pattern includes four sides toward four directions, respectively,
a side of the basic pattern to which the one or more additional patterns are connected among the four sides of the basic pattern is referred to as a first side,
a length of a boundary line between the one or more additional patterns connected to the first side and the first side is smaller than a length of the first side, and
a portion of the first side which is not connected with the one or more additional patterns and is exposed forms the exposed side.

15. The method of claim 14, wherein:
a length of the exposed side is greater than or equal to approximately 1/10 of the length of the first side.

16. The method of claim 15, wherein:
the one or more additional patterns are each in contact with two adjacent sides among the four sides of the basic pattern.

17. The method of claim 16, wherein:
the solder includes a solder fillet formed along a side surface of the electronic component, and
the solder fillet is at least partially positioned on the one or more additional patterns.

18. The method of claim 13, wherein:
the solder includes a solder fillet formed along a side surface of the electronic component, and
the solder fillet is at least partially positioned on the one or more additional patterns.

19. The method of claim 13, wherein:
the basic pattern includes four sides arranged in four directions, respectively,
a side of the basic pattern to which the one or more additional patterns are connected among the four sides of the basic pattern is referred to as a first side,
a length of a boundary line between the one or more additional patterns connected to the first side and the first side is approximately the same as a length of the first side,
an angle between a tangential line contacting the additional pattern at a contact point of a side of the additional pattern and a side of the basic pattern and a first direction in which the first side faces is smaller than an angle between a tangential line contacting the basic pattern at the contact point and the first direction, and
the contact point forms the exposed point.

20. The method of claim 19, wherein:
a shape of the one or more additional patterns is a circle, an ellipse, or a polygon having an acute angle at the exposed point.

21. A printed circuit board, comprising:
an insulating substrate;
a circuit pattern formed on the insulating substrate;
a solder resist layer formed on the circuit pattern;
an opening in the solder resist layer exposing a connection pattern of the circuit pattern; and
a pad pattern formed on the solder resist layer, the pad pattern electrically and physically connected to the connection pattern and supplementing adhesion between the circuit pattern and an external device,
wherein the pad pattern includes a basic pattern and one or more additional patterns connected to the basic pattern,
wherein the external device is attached by solder to a first region of the basic pattern and is not attached to the one or more additional patterns and the basic pattern includes an exposed side or an exposed point arranged to limit a mounting position of the external device and to prevent the external device from shifting in excess of a predetermined alignment margin.
